(19) United States
(12) Patent Application Publication
(10) Pub. No.: US 2008/0318165 A1
(43) Pub. Date: Dec. 25, 2008

(54) Composition For Forming Antireflective Film And Wiring Forming Method Using Same

(75) Inventors: Takeshi Tanaka, Kawasaki-shi (JP); Yoshinori Sakamoto, Kawasaki-shi (JP); Masaru Takahama, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 11/575,299

(22) PCT Filed: Aug. 31, 2005
(86) PCT No.: PCT/JP2005/015907

§ 371 Date: Mar. 14, 2007

(30) Foreign Application Priority Data
Sep. 16, 2004 (JP) 2004-269705

(51) Int. Cl. G03F 7/004; C08G 77/04; C08L 83/05; C08L 83/06

(52) U.S. Cl. 430/313; 528/33; 525/477; 525/478

(57) ABSTRACT

A material for forming an antireflective film that enables a large difference in etching rates to be obtained between a resist pattern and an antireflective film.

A composition for forming an antireflective film includes a siloxane polymer containing a light-absorbing compound group.

### TECHNICAL FIELD

The present invention relates to a composition for forming an antireflective film, and a wiring forming method using the same.

Priority is claimed on Japanese Patent Application No. 2004-269705, filed Sep. 16, 2004, the content of which is incorporated herein by reference.

### BACKGROUND ART

In recent years, ongoing miniaturization of semiconductor integrated circuits has lead to thinner resist films, and as a result, an antireflective film is often provided as a lower layer beneath the resist layer (for example, see patent reference 1 listed below). An acrylic-based or imide-based organic resin has conventionally been used as the material for this antireflective film.

For example, when an antireflective film formed from an acrylic-based resin is provided, then following formation of a resist pattern by patterning of the resist layer positioned on top of the antireflective film, and prior to patterning of the base body positioned beneath the antireflective film, a step is required for dry etching the antireflective film using the resist pattern as a mask.

Furthermore, patent reference 2 listed below discloses a wiring forming method that uses a via-first dual damascene method, wherein via holes are formed in an interlayer insulating film, the via holes are filled with a filling material, a resist pattern is formed on top of the filling material layer, and etching is then conducted using the resist pattern as a mask, thereby removing the filling material from the via holes and etching the interlayer insulating film so as to widen the trench width at the top of the via holes, thus forming trenches (wiring trenches) that connect with the via holes.

Moreover, a gap filling material formed from an organic material that combines a filling function and an antireflective function is disclosed in patent reference 3 listed below.

Furthermore, patent reference 4 listed below discloses a material for an antireflective film formed from an inorganic material.

[Patent Reference 1]

Japanese Unexamined Patent Application, First Publication No. 2001-27810

[Patent Reference 2]

U.S. Pat. No. 6,365,529 (U.S. Pat. No. 6,365,529 B1)

[Patent Reference 3]

Japanese Unexamined Patent Application, First Publication No. 2003-57828

[Patent Reference 4]

Japanese Unexamined Patent Application, First Publication No. 2003-502449

### DISCLOSURE OF INVENTION

### Problems to be Solved by the Invention

In those cases where, as described above, an antireflective film formed from an acrylic-based organic resin or the like is provided as a lower layer beneath the resist layer, the process of dry etching the antireflective film using the resist pattern as a mask involves conducting etching of an organic material (the antireflective film) with another organic material (the resist pattern) as a mask, and the etching rate of these two materials is similar. In other words, because the resist pattern undergoes etching at the same time as the etching of the antireflective film, conducting the etching process with favorable efficiency is problematic. As a result, the resist pattern must be formed as a thick film, which is a considerable impediment to the aforementioned trend towards thinner resist films that has accompanied ongoing miniaturization.

Accordingly, a technique that enables a greater difference to be obtained between the etching rates of the resist pattern and the antireflective film has been keenly sought.

Furthermore, in the via-first dual damascene method, a technique has been proposed in which an antireflective film (BARC) is provided between the filling material layer and the resist layer, but from a process perspective, imparting the filling material layer with an antireflective function would be more advantageous, and the development of a material that would be ideal for forming such a filling material layer having an antireflective function has been much anticipated.

As disclosed in the above patent reference 3, filling material layers that use an organic resin and have an antireflective function have been proposed, but organic resins suffer from the aforementioned etching rate problem.

In addition, as disclosed in the above patent reference 4, inorganic material-based antireflective films have been proposed, but these materials have not been developed with due consideration of the filling properties.

The present invention has been designed to address the problems outlined above, and has an object of providing a material for forming an antireflective film that enables the formation of an antireflective film with a large difference in etching rate relative to that of the resist pattern.

Furthermore, another object of the present invention is to provide a material for forming an antireflective film that enables the formation, within a via-first dual damascene method, of an antireflective film having both an antireflective function and a filling function, as well as a wiring forming method that uses such a material.

### Means for Solving the Problems

In order to achieve the above objects, a first aspect of the present invention provides a composition for forming an antireflective film that includes (A) a siloxane polymer containing a light-absorbing compound group.

Furthermore, a second aspect of the present invention provides a wiring forming method that includes: applying a composition for forming an antireflective film of the present invention to a base body containing an uppermost layer with holes formed therein, thereby forming an antireflective film; forming a resist layer on top of the antireflective film; patterning the resist layer, thereby forming a resist pattern having exposed regions at least above the holes; conducting etching of the antireflective film and the uppermost layer using the resist pattern as a mask, thereby forming a trench pattern that interconnects with the holes within the upper portion of the uppermost layer; and following formation of the trench pattern, removing the resist pattern and the antireflective film.

### Effects of the Invention

According to a composition for forming an antireflective film (a material for forming an antireflective film) of the present invention, an antireflective film can be formed that exhibits a large difference in etching rate from that of a resist pattern.

Furthermore, a composition for forming an antireflective film (a material for forming an antireflective film) of the present invention can be used favorably as the material for forming a filling layer in a via-first dual damascene method. According to a wiring forming method of the present invention, an antireflective film that exhibits both an antireflective function and a filling function can be formed, which is advantageous from a process perspective.

### BRIEF DESCRIPTION OF THE DRAWINGS

FIG. 1 is a diagram showing one step in an example of a wiring forming method according to the present invention.

FIG. 2 is diagram showing a step following the step of FIG. 1.

FIG. 3 is diagram showing a step following the step of FIG. 2.

FIG. 4 is diagram showing a step following the step of FIG. 3.

FIG. 5 is diagram showing a step following the step of FIG. 4.

### DESCRIPTION OF THE REFERENCE SYMBOLS

1 Substrate

2 Wiring layer

3 Barrier layer

4 Interlayer insulating film

5 Filling material layer (antireflective film)

6 Resist pattern

10 Base body

11 Via hole

12 Trench pattern

### BEST MODE FOR CARRYING OUT THE INVENTION

### <Component (A)>

A composition for forming an antireflective film of the present invention includes (A) a siloxane polymer containing a light-absorbing compound group (hereafter also referred to as the component (A)).

In other words, the component (A) is a polymer with a backbone formed from siloxane linkages (Si—O—Si). In addition, light-absorbing compound groups are bonded to silicon atoms of the siloxane linkages as substituent groups.

Siloxane polymers are generally synthesized by a hydrolysis reaction of a silane compound. Accordingly, siloxane polymers may also include low molecular weight hydrolysis products, and condensation products (siloxane oligomers) generated by a dehydration condensation reaction between molecules that occurs at the same time as the hydrolysis reaction. In those cases where the siloxane polymer used as the component (A) of the present invention contains these types of hydrolysis products and condensation products, the term “siloxane polymer” refers to the entire component, including these other products.

Although there are no particular restrictions on the backbone structure of the siloxane polymer used as the component (A), siloxane ladder polymers are particularly desirable. The reason for this preference is that such polymers enable the formation of particularly dense films.

Although there are no particular restrictions on the weight average molecular weight (Mw) (the polystyrene-equivalent value determined by gel permeation chromatography, this also applies to subsequent molecular weight values) of the component (A), the molecular weight is preferably within a range from 1,500 to 30,000, even more preferably from 3,000 to 20,000, and is most preferably from 5,000 to 15,000.

In the component (A), the light-absorbing compound group refers to a group having a structure that exhibits light absorption at the wavelength of the exposure light source which, during the exposure step, is irradiated onto the resist layer that is formed on top of the antireflective film formed using the composition for forming an antireflective film according to the present invention.

The wavelength of the exposure light used during the resist layer exposure step is generally no larger than 250 nm, and is usually within a range from approximately 157 to 248 nm.

Groups having a carbon double bond are ideal as the light-absorbing compound group, and groups having an aromatic ring such as a naphthalene ring, benzene ring, quinoline ring, quinoxaline ring or thiazole ring can be used favorably. Groups containing a benzene ring are preferred in those cases where the wavelength band of the exposure light is in the vicinity of 193 nm, and for example, groups obtained by removing one hydrogen atom from a benzene ring (which may include substituent groups) are particularly desirable. In the case of exposure light in the vicinity of 248 nm, groups containing an anthracene ring are preferred, and for example, groups obtained by removing one hydrogen atom from an anthracene ring (which may include substituent groups) are particularly desirable.

The aforementioned groups containing a benzene ring or anthracene ring, presented as examples of groups having an aromatic ring, may include substituent groups. Examples of these substituent groups include alkyl groups, alkoxy groups, hydroxyl groups, amino groups, amide groups, nitro groups, carboxyl groups, sulfone groups, cyano groups, and halogen atoms.

The light-absorbing compound groups within the component (A) may be of a single type, or may include groups of two or more different types.

There are no particular restrictions on the proportion of the light-absorbing compound group within the component (A), although when an antireflective film is formed using the composition for forming an antireflective film of the present invention, the k value (extinction coefficient) preferably falls within a range from 0.002 to 0.95.

Either a portion of, or all of, the light-absorbing compound groups that exist within the component (A) preferably contain a hydrophilic group, and those cases where only a portion of the light-absorbing compound groups contain a hydrophilic group are particularly preferred. A light-absorbing compound group containing a hydrophilic group refers to a group that has a structure that exhibits light absorption, and also contains a hydrophilic group. Of the possible hydrophilic groups, a hydroxyl group is particularly desirable.

Examples of groups that can be used as a light-absorbing compound group containing a hydrophilic group include groups in which a hydrophilic group is bonded to a carbon atom that forms part of a benzene ring, and groups in which a hydrophilic group is bonded to a carbon atom that forms part of an anthracene ring. Of these, a hydroxyphenylalkyl group is preferred.

The hydrophilic group within the component (A) may be of a single type, or may include groups of two or more different types.

There are no particular restrictions on the proportion of hydrophilic groups within the component (A), although in order to ensure a favorable improvement in the filling properties, the hydrophilic groups are preferably bonded to approximately 10 to 90%, and even more preferably 50 to 80%, of the above light-absorbing compound groups.

The component (A) can be synthesized by conventional methods. Furthermore, siloxane polymers that are suitable for use as the component (A) of the present invention may also be selected from siloxane polymers that are available commercially for applications other than the formation of antireflective films.

Of the various materials that can be used as the component (A), ladder-type silicone polymers that include a structural unit represented by a formula (a) shown below and a structural unit represented by a formula (b) shown below are particularly preferred.

Furthermore, in these ladder-type silicone polymers, the quantity of the structural unit represented by the formula (b) is preferably within a range from 10 to 90 mol %, and even more preferably from 20 to 80 mol %.

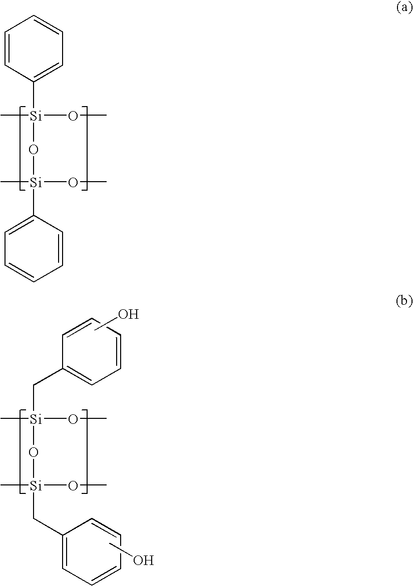

### <Component (B)>

Besides the component (A) described above, a composition for forming an antireflective film according to the present invention preferably also includes a siloxane polymer that does not contain a light-absorbing compound group (hereafter also referred to as the component (B)).

The component (B) is a polymer with a backbone formed from siloxane linkages (Si—O—Si), and there are no particular restrictions on the structure provided it is not included within the definition of the component (A), although reaction products obtained by a hydrolysis reaction of at least one compound selected from the silane compounds represented by a general formula (I) shown below are preferred.

These reaction products may also include low molecular weight hydrolysis products, and condensation products (siloxane oligomers) generated by a dehydration condensation reaction between molecules that occurs at the same time as the hydrolysis reaction. In those cases where the siloxane polymer used as the component (B) of the present invention contains these types of hydrolysis products and condensation products, the term “siloxane polymer” refers to the entire component, including these other products.

R₄₋ₙSi(OR′)ₙ (I)

In the general formula (I), R represents a hydrogen atom or an alkyl group, R′ represents an alkyl group, and n represents an integer from 2 to 4. In those cases where a plurality of R groups are bonded to the Si atom, the plurality of R groups may be either the same or different. Furthermore, the plurality of (OR′) groups bonded to the Si atom may be either the same or different.

The alkyl group represented by R is preferably a straight-chain or branched alkyl group of 1 to 20 carbon atoms, and is even more preferably a straight-chain or branched alkyl group of 1 to 4 carbon atoms.

The alkyl group represented by R′ is preferably a straight-chain or branched alkyl group of 1 to 5 carbon atoms. In terms of the speed of hydrolysis, the alkyl group represented by R′ is most preferably a group of 1 or 2 carbon atoms.

Silane compounds (i) of the general formula (I) in which the value of n is 4 can be represented by a general formula (II) shown below.

Si(OR¹)ₐ(OR²)_{b}(OR³)_{c}(OR⁴)_{d} (II)

In this formula, R¹, R², R³, and R⁴ each represent, independently, an alkyl group as defined above for R′.

a, b, c, and d are integers that satisfy the conditions: 0≦a≦4, 0≦b≦4, 0≦c≦4, 0≦d≦4, and a+b+c+d=4.

Silane compounds (ii) of the general formula (I) in which the value of n is 3 can be represented by a general formula (III) shown below.

R⁵Si(OR⁶)ₑ(OR⁷)_{f}(OR⁸)_{g} (III)

In this formula, R⁵ represents a hydrogen atom or an alkyl group as defined above for R. R⁶, R⁷, and R⁸ each represent, independently, an alkyl group as defined above for R′.

e, f, and g are integers that satisfy the conditions: 0≦e≦3, 0≦f≦3, 0≦g≦3, and e+f+g=3.

Silane compounds (iii) of the general formula (I) in which the value of n is 2 can be represented by a general formula (IV) shown below.

R⁹R¹⁰Si(OR¹¹)ₕ(OR¹²)ᵢ (IV)

In this formula, R⁹ and R¹⁰ each represent a hydrogen atom or an alkyl group as defined above for R. R¹¹ and R¹² each represent, independently, an alkyl group as defined above for R′.

h and i are integers that satisfy the conditions: 0≦h≦2, 0≦i≦2, and h+i=2.

Specific examples of the silane compounds (i) include tetraalkoxysilanes such as tetramethoxysilane, tetraethoxysilane, tetrapropoxysilane, tetrabutoxysilane, tetrapentyloxysilane, trimethoxymonoethoxysilane, dimethoxydiethoxysilane, triethoxymonomethoxysilane, trimethoxymonopropoxysilane, monomethoxytributoxysilane, monomethoxytripentyloxysilane, dimethoxydipropoxysilane, tripropoxymonomethoxysilane, trimethoxymonobutoxysilane, dimethoxydibutoxysilane, triethoxymonopropoxysilane, diethoxydipropoxysilane, tributoxymonopropoxysilane, dimethoxymonoethoxymonobutoxysilane, diethoxymonomethoxymonobutoxysilane, diethoxymonopropoxymonobutoxysilane, dipropoxymonomethoxymonoethoxysilane, dipropoxymonomethoxymonobutoxysilane, dipropoxymonoethoxymonobutoxysilane, dibutoxymonomethoxymonoethoxysilane, dibutoxymonoethoxymonopropoxysilane and monomethoxymonoethoxymonopropoxymonobutoxysilane, and of these, tetramethoxysilane and tetraethoxysilane are preferred.

Specific examples of the silane compounds (ii) include trimethoxysilane, triethoxysilane, tripropoxysilane, tripentyloxysilane, dimethoxymonoethoxysilane, diethoxymonomethoxysilane, dipropoxymonomethoxysilane, dipropoxymonoethoxysilane, dipentyloxymonomethoxysilane, dipentyloxymonoethoxysilane, dipentyloxymonopropoxysilane, methoxyethoxypropoxysilane, monopropoxydimethoxysilane, monopropoxydiethoxysilane, monobutoxydimethoxysilane, monopentyloxydiethoxysilane, methyltrimethoxysilane, methyltriethoxysilane, methyltripropoxysilane, methyltripentyloxysilane, ethyltrimethoxysilane, ethyltripropoxysilane, ethyltripentyloxysilane, propyltrimethoxysilane, propyltriethoxysilane, propyltripentyloxysilane, butyltrimethoxysilane, butyltriethoxysilane, butyltripropoxysilane, butyltripentyloxysilane, methylmonomethoxydiethoxysilane, ethylmonomethoxydiethoxysilane, propylmonomethoxydiethoxysilane, butylmonomethoxydiethoxysilane, methylmonomethoxydipropoxysilane, methylmonomethoxydipentyloxysilane, ethylmonomethoxydipropoxysilane, ethylmonomethoxydipentyloxysilane, propylmonomethoxydipropoxysilane, propylmonomethoxydipentyloxysilane, butylmonomethoxydipropoxysilane, butylmonomethoxydipentyloxysilane, methylmethoxyethoxypropoxysilane, propylmethoxyethoxypropoxysilane, butylmethoxyethoxypropoxysilane, methylmonomethoxymonoethoxymonobutoxysilane, ethylmonomethoxymonoethoxymonobutoxysilane, propylmonomethoxymonoethoxymonobutoxysilane and butylmonomethoxymonoethoxymonobutoxysilane, and of these, trimethoxysilane, triethoxysilane, and methyltrimethoxysilane are preferred.

Specific examples of the silane compounds (iii) include dimethoxysilane, diethoxysilane, dipropoxysilane, dipentyloxysilane, methoxyethoxysilane, methoxypropoxysilane, methoxypentyloxysilane, ethoxypropoxysilane, ethoxypentyloxysilane, methyldimethoxysilane, methylmethoxyethoxysilane, methyldiethoxysilane, methylmethoxypropoxysilane, methylmethoxypentyloxysilane, ethyldipropoxysilane, ethylmethoxypropoxysilane, ethyldipentyloxysilane, propyldimethoxysilane, propylmethoxyethoxysilane, propylethoxypropoxysilane, propyldiethoxysilane, propyldipentyloxysilane, butyldimethoxysilane, butylmethoxyethoxysilane, butyldiethoxysilane, butylethoxypropoxysilane, butyldipropoxysilane, butylmethyldipentyloxysilane, dimethyldimethoxysilane, dimethylmethoxyethoxysilane, dimethyldiethoxysilane, dimethyldipentyloxysilane, dimethylethoxypropoxysilane, dimethyldipropoxysilane, diethyldimethoxysilane, diethylmethoxypropoxysilane, diethyldiethoxysilane, diethylethoxypropoxysilane, dipropyldimethoxysilane, dipropyldiethoxysilane, dipropyldipentyloxysilane, dibutyldimethoxysilane, dibutyldiethoxysilane, dibutyldipropoxysilane, dibutylmethoxypentyloxysilane, methylethyldimethoxysilane, methylethyldiethoxysilane, methylethyldipropoxysilane, methylethyldipentyloxysilane, methylpropyldimethoxysilane, methylpropyldiethoxysilane, methylbutyldimethoxysilane, methylbutyldiethoxysilane, methylbutyldipropoxysilane, methylethylethoxypropoxysilane, ethylpropyldimethoxysilane, ethylpropylmethoxyethoxysilane, dipropyldimethoxysilane, dipropylmethoxyethoxysilane, propylbutyldimethoxysilane, propylbutyldiethoxysilane, dibutylmethoxyethoxysilane, dibutylmethoxypropoxysilane, and dibutylethoxypropoxysilane, and of these, dimethoxysilane, diethoxysilane, methyldimethoxysilane, and methyldiethoxysilane are preferred.

The silane compound used in the synthesis of the component (B) can be selected appropriately from the above silane compounds (i) to (iii).

The component (B) is preferably an organosiloxane polymer containing organic groups as silicon atom substituent groups, and in order to obtain such organosiloxane polymers, the use of at least a silane compound (ii) and/or a silane compound (iii) is preferred.

A particularly preferred combination is a combination of a silane compound (i) and a silane compound (ii). In those cases where a silane compound (i) and a silane compound (ii) are used, the respective proportions of these compounds are preferably from 90 to 10 mol % for the silane compound (i), and from 10 to 90 mol % for the silane compound (ii).

Although there are no particular restrictions on the weight average molecular weight (Mw) of the component (B), values from 1,000 to 3,000 are preferred, and values from 1,200 to 2,700 are particularly desirable.

There are no particular restrictions on the backbone structure of the component (B), although a siloxane ladder polymer is particularly desirable.

The component (B) can be prepared, for example, by a method in which one or more compounds selected from the aforementioned silane compounds (i) through (iii) is subjected to a hydrolysis-condensation reaction in the presence of an acid catalyst, water, and an organic solvent.

The above acid catalyst can use either an organic acid or an inorganic acid.

Examples of suitable inorganic acids include sulfuric acid, phosphoric acid, nitric acid, and hydrochloric acid, and of these, phosphoric acid and nitric acid are preferred.

Examples of suitable organic acids include carboxylic acids such as formic acid, oxalic acid, fumaric acid, maleic acid, glacial acetic acid, acetic anhydride, propionic acid and n-butyric acid, and organic acids having a sulfur-containing acid residue.

Examples of the above organic acids having a sulfur-containing acid residue include organic sulfonic acids, and esterified products thereof such as organic sulfate esters and organic sulfite esters. Of these, organic sulfonic acids such as compounds represented by a general formula (V) shown below are preferred.

R¹³—X (V)

(wherein, R¹³ represents a hydrocarbon group that may contain a substituent group, and X represents a sulfonic acid group)

In the above general formula (V), the hydrocarbon group represented by R¹³ is preferably a hydrocarbon group of 1 to 20 carbon atoms, and this hydrocarbon group may be either saturated or unsaturated, and may have a straight-chain, branched, or cyclic structure.

In those cases where the hydrocarbon group represented by R¹³ is cyclic, an aromatic hydrocarbon group such as a phenyl group, naphthyl group, or anthryl group is preferred, and of these, a phenyl group is particularly preferred. The aromatic ring within this aromatic hydrocarbon group may have either one, or a plurality of hydrocarbon groups of 1 to 20 carbon atoms bonded thereto as substituent groups. The hydrocarbon groups that function as these aromatic ring substituent groups may be either saturated or unsaturated, and may have a straight-chain, branched, or cyclic structure.

Furthermore, the hydrocarbon group represented by R¹³ may contain either one, or a plurality of substituent groups, and examples of these substituent groups include a halogen atom such as a fluorine atom, a sulfonic acid group, carboxyl group, hydroxyl group, amino group, or cyano group.

From the viewpoint of improving the shape of the lower portions of the resist pattern, the organic sulfonic acid represented by the above general formula (V) is preferably nonafluorobutanesulfonic acid, methanesulfonic acid, trifluoromethanesulfonic acid, dodecylbenzenesulfonic acid, or a mixture thereof.

The acid catalyst described above acts as a catalyst for the hydrolysis of the silane compound in the presence of water, and the quantity of water added is preferably within a range from 1.5 to 4.0 mols per 1 mol of the combination of silane compounds used. The acid catalyst may either be added after the addition of water, or the acid catalyst and water may be mixed together in advance and added as an acid aqueous solution. The quantity used of the acid catalyst is preferably adjusted to yield a concentration within the hydrolysis reaction system of 1 to 1,000 ppm, and even more preferably from 5 to 500 ppm. Moreover, the hydrolysis reaction is typically completed within approximately 5 to 100 hours, although heating at a temperature not exceeding 80° C. may be used to shorten the reaction time.

Examples of organic solvents that can be used in the synthesis of the siloxane polymer include monovalent alcohols such as methanol, ethanol, propanol and n-butanol, alkyl carboxylate esters such as methyl 3-methoxypropionate and ethyl 3-ethoxypropionate, polyvalent alcohols such as ethylene glycol, diethylene glycol, propylene glycol, glycerol, trimethylolpropane and hexanetriol, monoethers of polyvalent alcohols such as ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, propylene glycol monomethyl ether, propylene glycol monoethyl ether, propylene glycol monopropyl ether and propylene glycol monobutyl ether, as well as monoacetates thereof, esters such as methyl acetate, ethyl acetate and butyl acetate, ketones such as acetone, methyl ethyl ketone and methyl isoamyl ketone, and polyvalent alcohol ethers obtained by fully alkyl-etherifying polyvalent alcohol ethers such as ethylene glycol dimethyl ether, ethylene glycol diethyl ether, ethylene glycol dipropyl ether, ethylene glycol dibutyl ether, propylene glycol dimethyl ether, propylene glycol diethyl ether, diethylene glycol dimethyl ether, diethylene glycol diethyl ether and diethylene glycol methyl ethyl ether.

The above organic solvents may be used either alone, or in combinations of two or more different solvents.

By using this type of method, a solution is obtained containing the above reaction product as the component (B), and this solution can be used either as is, or following substitution of the solvent with a different solvent, as the component (B) of the composition for forming an antireflective film.

In those cases where a composition for forming an antireflective film containing both the component (A) and the component (B) is prepared, the mixing ratio of the component (A) and the component (B) can be determined in accordance with the properties being targeted. For example, by appropriate alteration of the proportion of the component (A) within the composition for forming an antireflective film, the refractive index (the n value) and the extinction coefficient (the k value) of the antireflective film can be controlled with ease.

More specifically, the mixing ratio (weight ratio) between the component (A) and the component (B) is preferably within a range from 99:1 to 1:99, even more preferably from 90:10 to 10:90, and is most preferably from 60:40 to 40:60.

In addition to the components (A) and (B) described above, a composition for forming an antireflective film according to the present invention may also include an organic solvent, an activating agent, a cross-linking accelerator, or an acid generator or the like.

### <Organic Solvent>

The organic solvent used in the synthesis of the component (A) or the component (B) may be included, as is, within the composition for forming an antireflective film. Furthermore, in order to achieve a preferred solid fraction concentration, dilution may also be conducted by adding a diluting solvent. This diluting solvent can be selected appropriately from the organic solvents listed above for use in the preparation of the component (B).

There are no particular restrictions on the quantity of organic solvent within the composition for forming an antireflective film, and the quantity can be set in accordance with the desired film thickness so as to produce a concentration that enables favorable application to a base body or the like. Generally, the solid fraction concentration of the composition for forming an antireflective film is adjusted to a value within a range from 2 to 20% by weight, and preferably from 5 to 15% by weight.

Of the various solvents, mixed solvents of a monovalent alcohol and an alkyl carboxylate ester yield particularly favorable filling properties, and are consequently preferred. In these mixed solvents, the mixing ratio between the monovalent alcohol and the alkyl carboxylate ester, expressed as a weight ratio, is preferably within a range from 20/80 to 80/20. Of the various possible mixtures, mixed solvents of n-butanol and methyl 3-methoxypropionate are particularly preferred.

Furthermore, the composition for forming an antireflective film may include alcohols derived from the organic solvent used in the preparation of the siloxane polymer, and/or alcohols generated by the silane compound hydrolysis reaction. Particularly in those cases where a silane compound of the general formula (I) in which R represents a hydrogen atom is used as the silane compound for producing the above reaction product, the quantity of alcohols contained within the composition for forming an antireflective film is preferably no more than 15% by weight. If a quantity of residual alcohol exceeding 15% by weight remains within the composition for forming an antireflective film, then the H—Si groups and the alcohols tend to be prone to reaction to form RO—Si groups, and as a result, not only does the composition for forming an antireflective film gel, leading to a deterioration in storage stability, but the composition also becomes prone to developing cracks. In those cases where an excessive quantity of alcohol is incorporated within the composition, the alcohol may be removed by evaporation under reduced pressure, which is typically conducted at a degree of vacuum within a range from 39.9×10² to 39.9×10³ Pa and preferably from 66.5×10² to 26.6×10³ Pa, and at a temperature of 20 to 50° C., for a period of 2 to 6 hours.

### <Method of Forming Antireflective Film>

A composition for forming an antireflective film of the present invention can be used favorably for forming an antireflective film provided as a lower layer beneath a resist layer. In order to form an antireflective film using a composition for forming an antireflective film of the present invention, the composition for forming an antireflective film is applied to the surface of a base body and then baked.

Specifically, the composition for forming an antireflective film that includes the component (A) (and may also include the component (B) and other components) can be used to form a film in the following manner. First, the composition for forming an antireflective film is applied to the base body in sufficient quantity to generate a predetermined film thickness, using a coating method such as spin coating, flow casting, or roll coating. The film thickness of the antireflective film may be set in accordance with the magnitude of the reflectance.

Subsequently, the applied composition for forming an antireflective film is baked on top of a hotplate. The bake temperature is typically within a range from 80 to 500° C., and preferably from 80 to 350° C. The time required for this baking is typically within a range from 10 to 360 seconds, and preferably from 90 to 210 seconds. The bake treatment may also be conducted over a plurality of stages with different bake temperatures.

Particularly in those cases where a siloxane polymer that includes structural units of the aforementioned formulas (a) and (b) is used as the component (A), simple baking at a temperature of less than 300° C. can be used to form an antireflective film that undergoes no mixing with the resist.

### <Wiring Forming Method>

Furthermore, a composition for forming an antireflective film of the present invention can also be used favorably as a via hole filling material in a wiring forming method that employs a via-first dual damascene method, enabling the formation of a filling material layer that also acts as an antireflective layer (antireflective film).

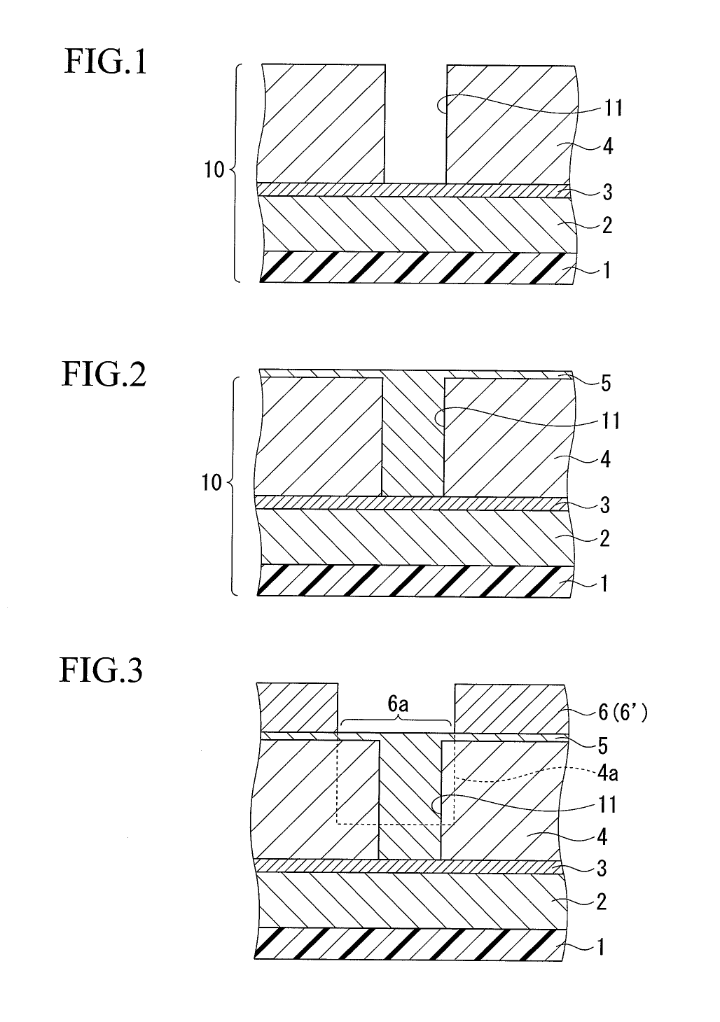

As follows is a description of one embodiment of a wiring forming method that uses a composition for forming an antireflective film of the present invention, with reference to FIG. 1 through FIG. 5.

Specifically, first, a base body 10 with a via hole 11 formed in the uppermost layer is formed as shown in FIG. 1. In the base body 10 of the example shown in FIG. 1, a wiring layer 2, a barrier layer 3, and an interlayer insulating film 4 are formed in sequence on top of a substrate 1, and a via hole 11 is formed that passes through the interlayer insulating film 4 that represents the uppermost layer. The via hole 11 can be formed using a photolithography method.

The wiring layer 2 is formed, for example, using a metal material such as copper, aluminum, or alloys thereof.

The barrier layer 3 has a function of preventing diffusion of the material of the wiring layer 2, and is formed from silicon nitride or the like.

The interlayer insulating film 4 uses an SOG film that includes SiO₂ or the like as the main component.

Next, as shown in FIG. 2, the composition for forming an antireflective film of the present invention is applied to the top of the base body 10 so as to fill the via hole 11, thereby forming a filling material layer (antireflective film) 5.

Subsequently, as shown in FIG. 3, a resist layer 6′ is formed on top of the filling material layer 5, and the resist layer 6′ is then patterned by conducting exposure and developing and the like, thereby forming a resist pattern 6. This resist pattern 6 is formed with a shape that, at the least, has an exposed region 6a above the via hole 11. This exposed region 6a is not covered by the resist pattern 6, and represents a region in which the filling material layer 5 is exposed. This exposed region 6a preferably has a width that is either similar to, or larger than, the diameter of the via hole 11.

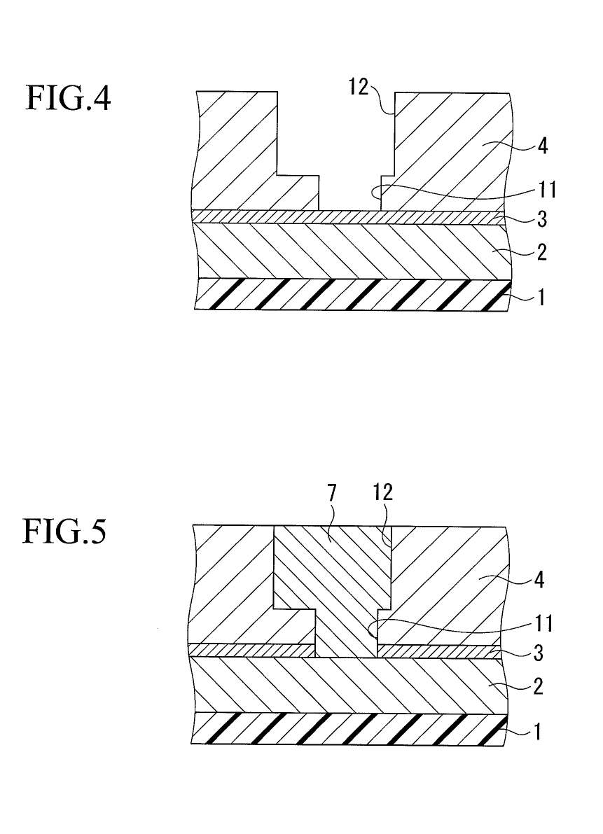

Subsequently, dry etching is conducted on the filling material layer 5 and at least an upper portion 4a of the interlayer insulating film 4 within the exposed region 6a, thereby forming a trench pattern (wiring trench) 12. In other words, as shown in FIG. 4, a trench pattern (wiring trench) 12 that interconnects with the via hole 11 is formed within the upper portion of the interlayer insulating film 4.

The residual resist pattern 6 left on top of the interlayer insulating film 4 and the residual filling material layer (antireflective film) 5 is then removed by a wet treatment. A stripping solution formed from an aqueous alkali solution containing an amine can be used favorably for this wet treatment. Furthermore, the barrier layer 3 exposed at the bottom of the via hole 11 can be removed by normal methods. The aqueous alkali solution containing an amine can use any of the conventional solutions that are typically used as photoresist stripping solutions. Examples of the amine include hydroxylamines, primary, secondary or tertiary aliphatic amines, alicyclic amines, aromatic amines or heterocyclic amines, as well as ammonia water, and quaternary amines such as lower alkyl quaternary ammonium salts. The use of quaternary amines is particularly preferred.

Subsequently, as shown in FIG. 5, wiring is formed by embedding a wiring material 7 such as copper within the via hole 11 and the trench pattern (wiring trench) 12.

Because a composition for forming an antireflective film according to the present invention includes light-absorbing compound groups, it is able to form a film that absorbs the exposure light irradiated onto the resist layer, thereby exhibiting an antireflective function.

An antireflective film formed from a composition for forming an antireflective film according to the present invention exhibits an etching rate upon dry etching that is significantly different to the etching rate of the resist pattern (an organic material). Moreover, the etching rate of the antireflective film approaches that of the interlayer insulating film, which is typically formed using an inorganic material. The reason for these observations is that a siloxane polymer, which has properties resembling those of an inorganic compound, is the main component of the antireflective film. Accordingly, the step of dry etching the antireflective film and the interlayer insulating film using the resist pattern (organic material) as a mask can be conducted with favorable efficiency, which enables the thickness of the resist to be reduced.

Furthermore, a composition for forming an antireflective film according to the present invention can be used favorably as the filling material within a via-first dual damascene method, and enables the formation of a filling material layer that has an antireflective function. Accordingly, the step of providing an antireflective film between the resist layer and the filling material layer becomes unnecessary, which contributes to a reduction in the number of steps required within the wiring forming method.

In those cases where the component (A) includes light-absorbing compound groups containing a hydrophilic group, the filling properties are particularly favorable.

In an embodiment in which the component (A) and the component (B) are mixed together, the refractive index (the n value) and the extinction coefficient (the k value) of the antireflective film can be controlled with ease by adjusting the mixing ratio between the component (A) and the component (B). Accordingly, the refractive index (the n value) and the extinction coefficient (the k value) can be optimized, facilitating the formation of a state that provides very low reflectance.

Furthermore, an embodiment that includes both the component (A) and the component (B) also offers the advantage of dissolving extremely well in an aqueous alkali solution containing an amine (an amine-based stripping solution).

In the case of an antireflective film formed from a conventional organic material, an ashing treatment must be used to remove the antireflective film following patterning of the base body beneath the antireflective film, but this ashing treatment may damage the base body (and particularly the interlayer insulating film). In contrast, an antireflective film formed from a composition for forming an antireflective film that includes both the component (A) and the component (B) can be removed easily using an amine-based stripping solution, meaning ashing treatment of the antireflective film is unnecessary, and thereby enabling damage of the base body (and particularly the interlayer insulating film) to be prevented.

For example, in the case where a composition for forming an antireflective film containing both the component (A) and the component (B) is used as the filling material within a wiring forming method that employs a via-first dual damascene method, damage to the layer beneath the filling material layer (in the above example, the interlayer insulating film) can be prevented by using an amine-based stripping solution in the filling material removal step that is conducted following the formation of the trench pattern.

Particularly in those cases where the component (A) uses a siloxane polymer that includes structural units of the aforementioned formulas (a) and (b), the solubility of the filling material in an aqueous alkali solution containing an amine (an amine-based stripping solution) is particularly favorable.

Furthermore, an embodiment that includes both the component (A) and the component (B) exhibits particularly improved filling properties, meaning even via holes with diameters of 80 nm can be filled with no voids. Particularly in the case of a wiring forming method that employs a via-first dual damascene method, if voids are generated within the via holes during filling of the via holes, then unfavorable deviations in the etching speed tend to develop during the etching step used for forming the trench pattern.

A composition for forming an antireflective film that includes both the component (A) and the component (B) also offers the advantage of being able to form a film without the requirement for a high-temperature curing step. An antireflective film that undergoes no mixing with the resist layer can be formed by conducting solely a baking treatment, with no curing step.

Particularly in those cases where the component (A) uses a siloxane polymer that includes structural units of the aforementioned formulas (a) and (b), an antireflective film that undergoes no mixing with the resist layer can be formed by simply conducting a baking treatment at a temperature of less than 300° C.

### EXAMPLES

### Example 1

### Preparation of a Composition for Forming an Antireflective Film

136.6 g of tetramethoxysilane, 117.8 g of methyltrimethoxysilane, 109 g of water, 220.8 g of n-butanol, and 220.8 g of methyl 3-methoxypropionate (MMP) were mixed together, 18.84 μl of an aqueous solution of nitric acid with a concentration of 60% by weight was added, and the resulting mixture was stirred for two hours. Subsequently, the mixture was aged by standing for three days at room temperature, yielding a solution containing a reaction product as the component (B). This reaction product includes a siloxane polymer having siloxane linkages represented by a chemical formula (1) shown below. The weight average molecular weight (Mw) of the thus obtained reaction product was 1,400.

Subsequently, 104 g of a siloxane polymer represented by a chemical formula (2) shown below (Mw=9,700) was added to the solution obtained above as the component (A). In the chemical formula (2), the value of the ratio x:y, which represents the molar ratio between each of the structural units, is 3:7.

A mixed solvent of n-butanol: MMP=1:1 (weight ratio) was then used to dilute the solution to a concentration that enables coating at a predetermined film thickness, thereby yielding a coating solution (a composition for forming an antireflective film).

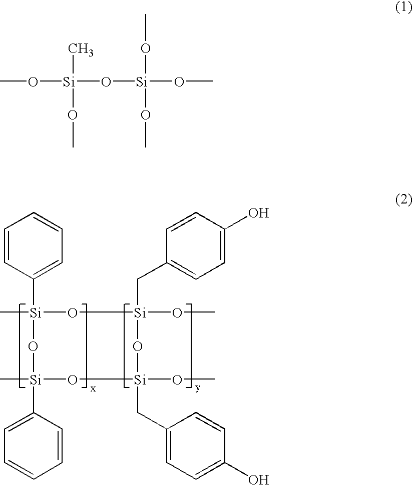

### Evaluation of Antireflective Performance

The thus obtained coating solution was spin coated onto a substrate, and subjected to a three stage baking treatment involving heating at 80° C. for 60 seconds, at 150° C. for 60 seconds, and then at 260° C. for 90 seconds, thereby forming an antireflective film.

When the antireflective film was measured and analyzed using a spectroscopic ellipsometer with an ArF excimer laser, the n value was 1.58 and the k value was 0.46.

Furthermore, when the relationship between the film thickness and the reflectance was simulated using a model in which the same antireflective film as above was formed on the top of a Si substrate and a typical ArF resist was then laminated thereon, the results revealed that the reflectance could be suppressed to approximately 2% for antireflective film thickness values of 900 Å or greater.

### valuation of Filling Properties

A base body was prepared in which an uppermost layer formed from SiO₂ and with holes of depth 420 nm and diameter 80 nm formed therein was provided on top of a substrate. The coating solution obtained in the example 1 was applied to the surface of this base body, and was then baked under the same conditions as those described in the example 1, thereby forming a filling material layer. Inspection of the cross-section of this filling material layer using an SEM revealed no void generation within the holes, indicating favorable filling properties.

### Evaluation of Resist Pattern Shape

When a resist film was formed using an ArF resist composition (product name: 6a-178, manufactured by Tokyo Ohka Kogyo Co., Ltd.) on top of an antireflective film formed using the above coating solution in the same manner as described above, no mixing of the films occurred, and a favorable resist layer was formed. When a line and space pattern of 130 nm was formed in this resist layer under normal conditions, a resist pattern was obtained in which the cross-sectional shape exhibited favorable rectangular formability.

### Evaluation of Stripping Properties

When an antireflective film formed using the above coating solution in the same manner as described above was immersed in a stripping solution containing a quaternary amine, the antireflective film dissolved extremely readily.

### Comparative Example 1

With the exception of not including the component (A), a coating solution was prepared in the same manner as the example 1.

The thus prepared coating solution was evaluated for antireflective performance, filling properties, resist pattern shape, and solubility in the same manner as the example 1.

### Evaluation of Antireflective Performance

A film obtained in the same manner as the example 1 but using the coating solution of this comparative example exhibited no light-absorbing capability, and had no antireflective function.

### Evaluation of Filling Properties

When the coating solution of this comparative example was used to form a filling material layer on top of a base body with holes formed therein, in the same manner as the example 1, voids were generated within the holes.

### Evaluation of Resist Pattern Shape

When the coating solution of this comparative example was used to form a film in the same manner as the example 1, a resist layer similar to that described above was formed on top of the film, and a resist pattern was then formed in the resist layer, the matching of the two layers was extremely poor, and tailing (footing) was observed in the resist pattern.

### Evaluation of Stripping Properties

When the coating solution of this comparative example was used to form a film in the same manner as the example 1, and the solubility of this film was then evaluated, the film of this comparative example exhibited almost no dissolution in the stripping solution.

1. A composition for forming an antireflective film, comprising (A) a siloxane polymer containing a light-absorbing compound group.

2. A composition for forming an antireflective film according to claim 1, wherein said component (A) comprises a light-absorbing compound group having a benzene ring.

3. A composition for forming an antireflective film according to claim 1, wherein said component (A) comprises a light-absorbing compound group having a hydrophilic group.

4. A composition for forming an antireflective film according to claim 2, wherein said component (A) comprises a light-absorbing compound group having a hydrophilic group.

5. A composition for forming an antireflective film according to claim 3, wherein said hydrophilic group is a hydroxyl group.

6. A composition for forming an antireflective film according to claim 4, wherein said hydrophilic group is a hydroxyl group.

7. A composition for forming an antireflective film according to claim 1, wherein said component (A) is a siloxane ladder polymer.

8. A composition for forming an antireflective film according to claim 1, wherein said component (A) comprises a structural unit represented by a formula (a) shown below: 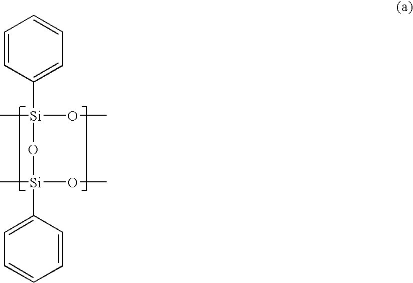
and a structural unit represented by a formula (b) shown below.

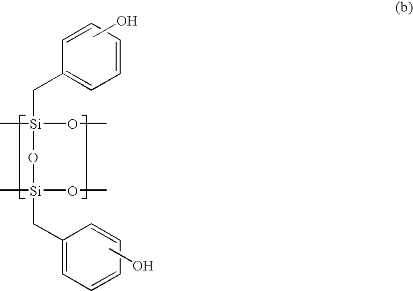

9. A composition for forming an antireflective film according to claim 1, further comprising (B) a siloxane polymer that does not contain a light-absorbing compound group.

10. A composition for forming an antireflective film according to claim 9, wherein said siloxane polymer (B) is a reaction product obtained by a hydrolysis reaction of at least one compound selected from amongst silane compounds represented by a general formula (I) shown below:
R₄₋ₙSi(OR′)ₙ (I)
(wherein, R represents a hydrogen atom or an alkyl group, R′ represents an alkyl group, and n represents an integer from 2 to 4).

11. A composition for forming an antireflective film according to claim 9, wherein said component (B) is a siloxane ladder polymer.

12. A wiring forming method, comprising:
applying a composition for forming an antireflective film according to any one of claim 1 through claim 11 to a base body comprising an uppermost layer with holes formed therein, thereby forming an antireflective film;
forming a resist layer on top of said antireflective film;
patterning said resist layer, thereby forming a resist pattern having exposed regions at least above said holes;
conducting etching of said antireflective film and said uppermost layer using said resist pattern as a mask, thereby forming a trench pattern that interconnects with said holes within an upper portion of said uppermost layer; and
following formation of said trench pattern, removing said resist pattern and said antireflective film.

13. A wiring forming method according to claim 12, wherein said removing said resist pattern and said antireflective film is conducted using a wet treatment.

14. A wiring forming method according to claim 13, wherein said wet treatment is conducted using an aqueous alkali solution containing an amine.
